(19) United States
(12) Patent Application Publication
(10) Pub. No.: US 2007/0148970 A1
(43) Pub. Date: Jun. 28, 2007

(54) Method of fabricating circuitry without conductive circle

(75) Inventors: Ting-Hao Lin, Taoyuan (TW); Chih-Wei Lee, Taoyuan (TW)

Correspondence Address: PATENTTM.US, P. O. BOX 82788, PORTLAND, OR, 97282-0788, US

(73) Assignee: GOLD CIRCUIT ELECTRONICS LTD.

(21) Appl. No.: 11/319,874

(22) Filed: Dec. 27, 2005

(51) Int. Cl. H01L 21/44

(52) U.S. Cl. 438/678; 257/E23.011

(57) ABSTRACT

A method of fabricating circuitry without conductive circles has steps of providing a plate with multiple apertures defined therein, the plate and inner walls of the apertures are coated with a copper layer; the copper layers are coated with a photoresist layer, which is then covered with a protective film; partly removing the photoresist layer at the apertures; removing the protective film to expose the photoresist layer; electroplating the inner walls of the apertures with copper; exposing and developing the photoresist layers; and finally, etching the copper layers to form a circuit pattern without any conductive circles.

### BACKGROUND OF THE INVENTION

1. Field of the Invention

The present invention relates to a method of fabricating a circuit board, and particularly relates to a method of fabricating circuitry on a circuit board without conductive circles.

2. Description of the Related Art

A conventional circuit board often has multiple through holes defined therein, and around each through hole, a conductive circle is formed, whereby pins of electrical components are inserted through the holes and soldered to the conductive circle to be electrically connected with the circuitry.

At present, the trend in circuit board design is towards miniaturization. With the development of smaller and smaller electronic products the circuitry involved is required to be accordingly miniaturized. However, the conductive circles limit circuit design and layout, which in turn limits the degree of miniaturization possible for a circuit board.

With reference to FIGS. 2A˜2F, a conventional method of fabricating a circuit board designed without conductive circles includes a plate (40) having a top surface and a bottom surface. Multiple apertures (41) are defined through the plate (40), and a copper layer (42) is coated on the top surface, the bottom surface and inner walls of those apertures (41), as shown in FIG. 2A. The apertures (41) are filled with light sensitive ink (43), as shown in FIG. 2B. The plate (40) is exposed to ultraviolet radiation, which causes the light sensitive ink (43) to solidify into a plug (44) as shown in FIG. 2B. The protruding portions of the plug (44) are then abraded to be flush with the surface of the plate (40), as shown in FIG. 2C. A photoresist layer (46) is coated on the copper layer (42), and processed by exposure, development and etching steps, as shown in FIG. 2D. A circuit pattern (45) as designed is then formed in the copper layer (42). The circuitry formed on the top surface and bottom surface are connected by the copper coating on the walls of the apertures (41), as shown in FIG. 2E. Finally, the photoresist layer (46) and the plug (44) are removed, as shown in FIG. 2F, resulting in a circuit board without any conductive circles.

However, it is possible that the apertures (41) are not completely filled with the light sensitive ink (43). In the etching process, the etching agent may leak into the apertures (41) to damage the copper layer (42), especially in a thin circuit board.

Therefore, the invention provides a method of fabricating circuitry without conductive circles to mitigate or obviate the aforementioned problems.

### SUMMARY OF THE INVENTION

The main objective of the present invention is to provide a method of fabricating circuitry without conductive circles, which has the following advantages:

1. Separately processing the two surfaces allows conventional electroplating techniques to be applied with precision to protect the copper layer in the apertures.

2. No-conductive circle design eliminates the requirement for alignment of through holes with exposure locations, and facilitates the layout design on the circuit board.

3. Localized electroplating means is capable of protecting the copper layer in the apertures, which prevents damage to the copper layer in the etching process, and can also effectively manage some thin-line circuitry.

4. The ink-filling step is omitted, which is makes the invention suitable for very thin circuit board manufacturing.

Other objectives, advantages and novel features of the invention will become more apparent from the following detailed description when taken in conjunction with the accompanying drawings.

### BRIEF DESCRIPTION OF THE DRAWINGS

FIGS. 1A˜1I are sectional views illustrating the steps of fabricating circuitry without conductive circles in accordance with this invention;

FIGS. 2A˜2F are sectional views illustrating the steps of fabricating circuitry without conductive circles in a conventional method.

### DETAILED DESCRIPTION OF THE PREFERRED EMBODIMENT

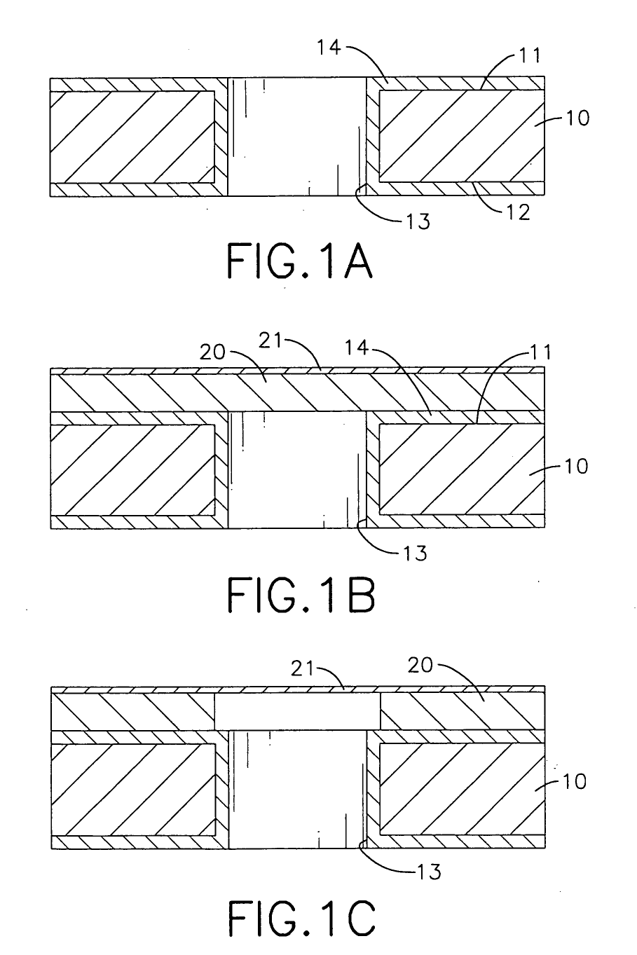

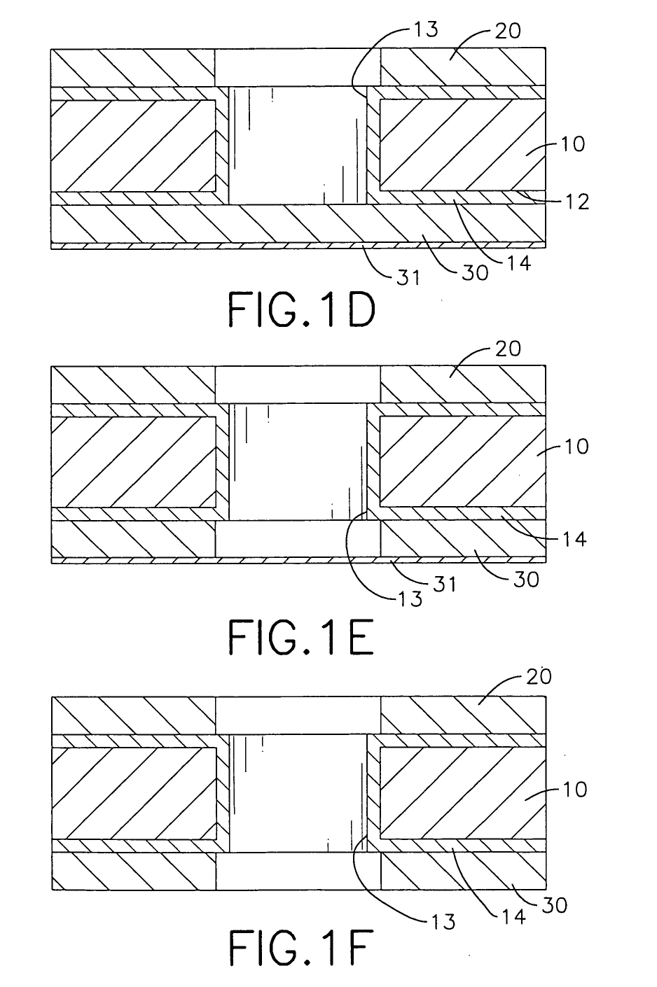

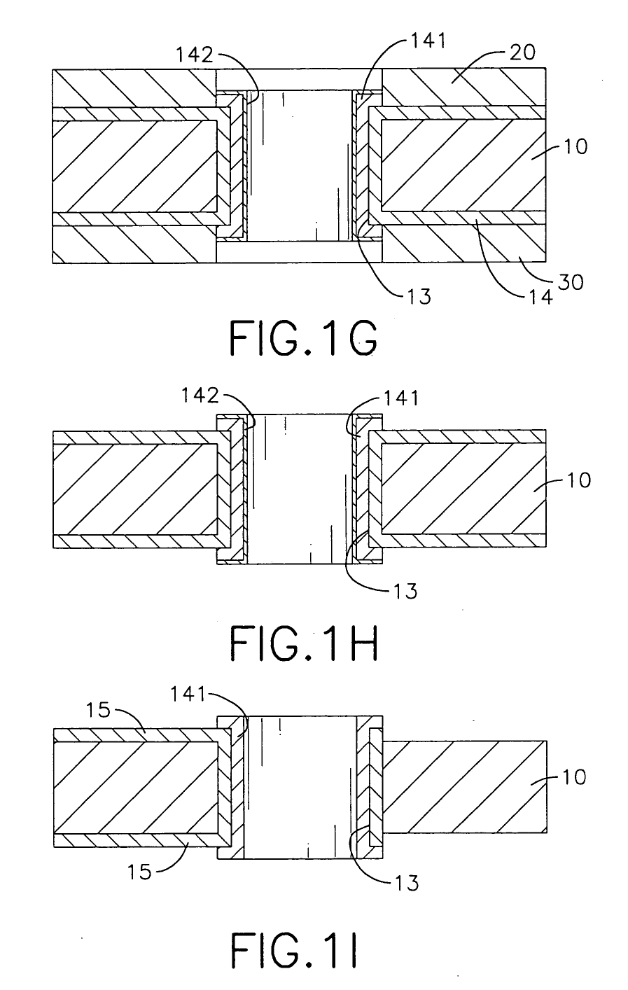

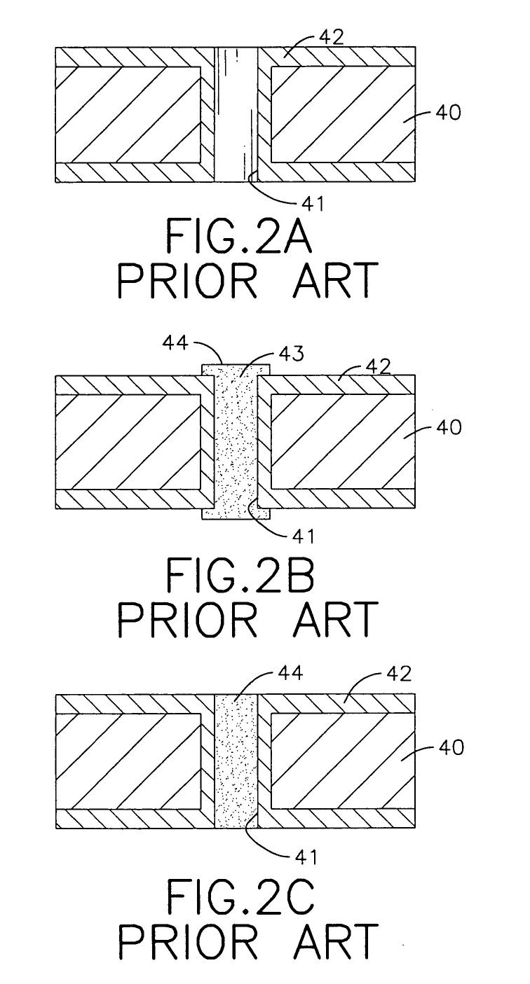

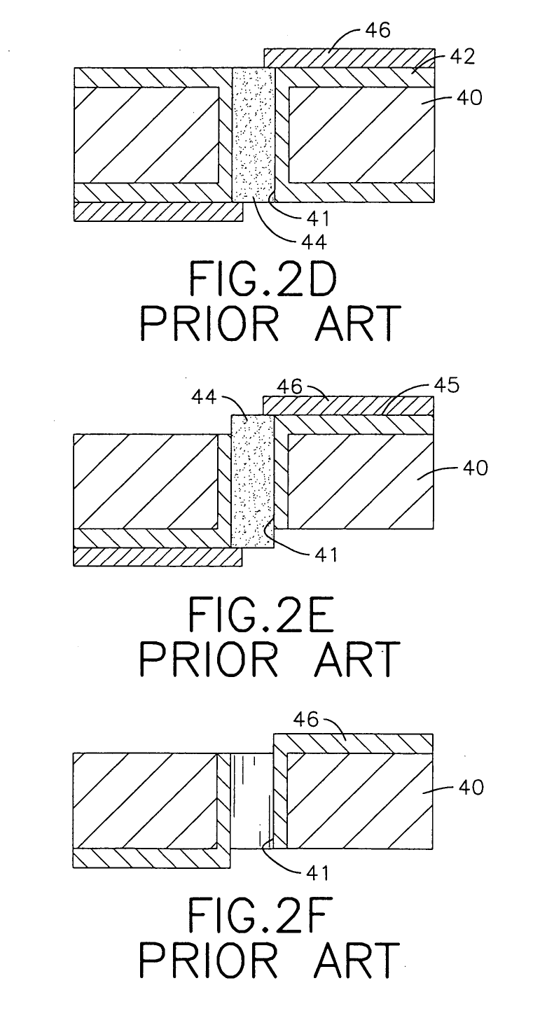

With reference to FIGS. 1A to 1I, a method of fabricating circuitry on a circuit board comprises the following steps:

A plate (10) is provided having a first surface (11), a second surface (12) and multiple apertures (13) defined through the first surface (11) and the second surface (12). The first surface (11), the second surface (12) and the inner walls of the apertures (13) are coated with a copper layer (14), as shown in FIG. 1A.

A first photoresist layer (20) is coated on the copper layer (14) of the first surface (11), and a first protective film (21) is spread over the first photoresist layer (20), as shown in FIG. 1B.

The first photoresist layer (20) is partly removed at the apertures (13) by exposing, developing and dissolving the photoresist. The apertures (13) are then cleaned and dried, as shown in FIG. 1C. The first protective film (21) is removed from the first photoresist layer (20).

A second photoresist layer (30) is coated on the copper layer (14) of the second surface (12), and a second protective film (31) is spread over the second photoresist layer (30), as shown in FIG. 1D. The second photoresist layer (30) is partly removed at the apertures (13) by exposing, developing and dissolving the photoresist. The apertures (13) are then cleaned and dried, as shown in FIG. 1E.

The second protective film (31) is removed from the second photoresist layer (30), as shown in FIG. 1F.

The inner walls of the apertures (13) are coated by electroplating with copper (141), as shown in FIG. 1G. This thickens the copper layer on the inner walls of the apertures (13). The copper electroplating can be followed with electroplating with tin (or other metal that cannot be easily oxidized) to form a protective layer (142) for the copper.

The photoecthing process is then performed. The first and second photoresists (20), (30) are exposed and developed. The etching process is executed to form a circuit pattern (15) in the copper layer (14) of the first and second surfaces (11), (12), as shown in FIG. 1H and FIG. 1I.

The method of fabricating circuitry on a circuit board in accordance with this invention is capable of protecting the copper layer on the inner walls of the apertures, eliminating the need for conductive circles as in conventional circuit boards, and also facilitates circuit layout and design at the same time. Localized electroplating thickens the copper layer in the apertures, preventing excessive damage to the copper layer during etching, and is well suited for thin circuit board manufacturing.

It is to be understood, however, that even though numerous characteristics and advantages of the present invention have been set forth in the foregoing description, together with details of the structure and function of the invention, the disclosure is illustrative only. Changes may be made in the details, especially in matters of shape, size, and arrangement of parts within the principles of the invention to the full extent indicated by the broad general meaning of the terms in which the appended claims are expressed.

What is claimed is:

1. A method of fabricating circuitry without conductive circles comprising the steps of:
providing a plate having a first surface and a second surface, multiple apertures defined through the first and second surfaces, wherein the first surface and the second surface and inner walls of the apertures are coated with a copper layer;
coating a first photoresist layer on the first surface of the plate, wherein the first photoresist layer is covered with a first protective film;
partly removing the first photoresist layer at the apertures through exposure, developing and dissolution;
removing the first protective film from the first photoresist layer;
coating a second photoresist layer on the second surface of the plate, wherein the second photoresist layer is covered with a second protective film;
partly removing the second photoresist layer at the apertures through exposure, developing and dissolution;
removing the second protective film from the second photoresist layer;
electroplating all inner walls of the apertures with copper; and
exposing, developing and etching in turn to form a circuit pattern in the copper layers of the first and second surfaces, wherein the first and second photoresists are exposed and developed, and the copper layer selectively etched. The circuitry on the first surface and the second surface are electrically connected by the copper layer on the inner walls of the apertures.

2. A method of fabricating circuitry without conductive circles as claimed in claim 1, wherein the electroplating with copper can be followed with electroplating with tin to form a protective layer for the copper.
